(19) United States
(12) Patent Application Publication
(10) Pub. No.: US 2026/0181935 A1
(43) Pub. Date: Jun. 25, 2026

(54) DUAL-PROCESS OXIDE TRENCH STRUCTURE FOR SILICON CARBIDE MOSFETS

(71) Applicant: Renesas Electronics Corporation, Tokyo (JP)

(72) Inventors: Kijeong HAN, Morrisville, NC (US); Meng Chia LEE, Dallas, TX (US); Dilip Madhav RISBUD, San Jose, CA (US); Eikyu KATSUMI, Tokyo (JP); Mitsuhisa TADA, Tokyo (JP)

(73) Assignee: Renesas Electronics Corporation, Tokyo (JP)

(21) Appl. No.: 18/989,698

(22) Filed: Dec. 20, 2024

(51) Int. Cl. H10D 30/01; H10D 30/66; H10D 62/10; H10D 62/832

(52) U.S. Cl. CPC H10D 30/0297; H10D 30/668; H10D 62/109; H10D 62/8325

(57) ABSTRACT

A method of forming a semiconductor device includes forming a first oxide layer having a first thickness to line a trench formed in a Silicon Carbide (SiC) substrate. The method further includes etching the first oxide layer to form a second oxide layer having the first thickness. A portion of the trench lined by the second oxide layer being less than a portion of the trench lined by the first oxide layer. The method further includes forming a third oxide layer having a second thickness on the trench and on a top surface of the second oxide layer. A combination of the second oxide layer and the third oxide layer forming an oxide region that lines different portions of the trench with different oxide thickness. The method further includes forming a gate electrode in the trench lined with the oxide region.

### BACKGROUND

The present disclosure generally relates to the field of semiconductor devices, and more particularly to silicon carbide trench metal-oxide-semiconductor field-effect transistors.

A metal-oxide-semiconductor field-effect transistor (MOSFET) cell can be a planar MOSFET or a trench MOSFET. When compared to planar MOSFETs, the trench structure in a trench MOSFET helps in achieving a more efficient control of the depletion region. By etching a trench vertically into the substrate and lining it with a gate oxide and a conductive material (typically polysilicon), the trench MOSFET can also achieve a higher packing density and reduce on-resistance compared to planar MOSFETs. The trench structure also helps in minimizing parasitic capacitances and improving thermal management. In an aspect, when Silicon Carbide (SiC) is used for forming the trench MOSFET, breakdown voltage is increased compared to Silicon (Si) trench MOSFETs because SiC has a larger bandgap than silicon (Si).

### SUMMARY

According to an embodiment of the present disclosure, a method of forming a semiconductor device includes forming a first oxide layer having a first thickness to line a trench formed in a Silicon Carbide (SiC) substrate, etching the first oxide layer to form a second oxide layer having the first thickness, with a portion of the trench lined by the second oxide layer being less than a portion of the trench lined by the first oxide layer, forming a third oxide layer having a second thickness on the trench and on a top surface of the second oxide layer, with a combination of the second oxide layer and the third oxide layer forming an oxide region that lines different portions of the trench with different oxide thickness, and forming a gate electrode in the trench lined with the oxide region.

According to another embodiment of the present disclosure, a method of forming a semiconductor device includes forming a first oxide layer having a first thickness to line a trench formed in a Silicon Carbide (SiC) substrate, etching the first oxide layer to form a second oxide layer having the first thickness, forming a third oxide layer having a second thickness on the trench and on a top surface of the second oxide layer, a combination of the second oxide layer and the third oxide layer creating an oxide region lining the trench, with the oxide region including a bottom portion, a lower side portion and an upper side portion lining different parts of the trench, and forming a gate electrode in the trench lined with the oxide region.

According to yet another embodiment of the present disclosure, a method of forming a semiconductor device includes forming a trench within a Silicon Carbide (SiC) substrate, forming a shield region on a bottom portion of the trench, forming a first oxide layer having a first thickness to line the trench, the first oxide layer being disposed above the shield region, depositing a conductive material on the first oxide layer, etching a portion of the first oxide layer that is non-overlapping with the conductive material to form a second oxide layer having the first thickness, conducting an oxidation process to form a third oxide layer having a second thickness on a top surface of the second oxide layer, a combination of the second oxide layer and the third oxide layer creating an oxide region of varying thickness, with the oxide region including a bottom portion, a lower side portion and an upper side portion each lining different parts of the trench, and forming a gate electrode in the trench lined with the oxide region.

### BRIEF DESCRIPTION OF THE DRAWINGS

The following detailed description, given by way of example and not intended to limit the embodiments described herein, will best be appreciated in conjunction with the accompanying drawings, in which:

FIG. 1 illustrates an example of a portion of a two-step oxide trench Silicon Carbide MOSFET in one embodiment;

FIG. 2 illustrates an example of a two-step oxide trench Silicon Carbide MOSFET in one embodiment;

FIG. 3 illustrates an example of an oxide region in a two-step oxide trench Silicon Carbide MOSFET in one embodiment;

FIG. 4A illustrates a step in a manufacturing process of a two-step oxide trench Silicon Carbide MOSFET in one embodiment;

FIG. 4B illustrates another step in a manufacturing process of a two-step oxide trench Silicon Carbide MOSFET in one embodiment;

FIG. 5A illustrates another step in a manufacturing process of a two-step oxide trench Silicon Carbide MOSFET in one embodiment;

FIG. 5B illustrates another step in a manufacturing process of a two-step oxide trench Silicon Carbide MOSFET in one embodiment;

FIG. 6A illustrates another step in a manufacturing process of a two-step oxide trench Silicon Carbide MOSFET in one embodiment;

FIG. 6B illustrates another step in a manufacturing process of a two-step oxide trench Silicon Carbide MOSFET in one embodiment;

FIG. 7A illustrates another step in a manufacturing process of a two-step oxide trench Silicon Carbide MOSFET in one embodiment;

FIG. 7B illustrates another step in a manufacturing process of a two-step oxide trench Silicon Carbide MOSFET in one embodiment;

FIG. 8A illustrates another step in a manufacturing process of a two-step oxide trench Silicon Carbide MOSFET in one embodiment;

FIG. 8B illustrates another step in a manufacturing process of a two-step oxide trench Silicon Carbide MOSFET in one embodiment;

FIG. 9A illustrates another example of a two-step oxide trench Silicon Carbide MOSFET in one embodiment;

FIG. 9B illustrates another step in a manufacturing process of a two-step oxide trench Silicon Carbide MOSFET in one embodiment;

FIG. 9C illustrates another step in a manufacturing process of a two-step oxide trench Silicon Carbide MOSFET in one embodiment;

FIG. 9D illustrates another step in a manufacturing process of a two-step oxide trench silicon carbide MOSFET in one embodiment;

FIG. 9E illustrates another step in a manufacturing process of a two-step oxide trench Silicon Carbide MOSFET in one embodiment; and

FIG. 10 is a flow diagram illustrating a process to manufacture a two-step oxide trench Silicon Carbide MOSFET in one embodiment.

The drawings are not necessarily to scale. The drawings are merely schematic representations, not intended to portray specific parameters of the embodiments in the present disclosure. The drawings are intended to depict typical embodiments of the present disclosure. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. The claimed structures and methods may, however, be embodied in many different forms and should not be construed as limited to the exemplary embodiments set forth herein. In the description, details of various conventional features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present disclosure, in the following detailed description, some processing steps or operations that may be ordinary in the art may have been combined together for presentation and for illustration purposes and in some instances may have not been described in detail. In other instances, some processing steps or operations that may be ordinary in the art may not be described at all. It should be understood that the following description is rather focused on the distinctive features or elements of various embodiments of the present disclosure.

A trench gate metal-oxide-semiconductor field-effect transistor (MOSFET) can handle significant power and provide a high-power drive capability by vertically conducting current from a top surface to a bottom surface of a semiconductor die. The trench gate MOSFET in its active region can include a large number of parallel connected active trench gate MOSFET cells each including a trench formed in the semiconductor die, with each active trench having surrounding source regions and oppositely-doped body regions, and the trenches can be deep enough to cross through the body regions to a drift region below the top surface of the semiconductor die. Each active trench gate cell has a gate buried in the trench that can include a gate electrode including doped polysilicon and a gate dielectric. The gate electrodes, when appropriately biased, can control the current conduction in the body region and enable the MOSFET cells to be turned on, thus enabling current to flow between the source and the drain from top to bottom.

Silicon Carbide (SiC) devices, when compared to Silicon (Si) devices, can provide higher breakdown voltage and withstand higher voltages. Thus, SiC devices, instead of Si devices, may be more suitable for high-power applications where high breakdown voltages are required. SiC devices also have lower ON-Resistance (RDSon) when compared to Si devices, and lower RDSon can lead to less conduction losses, thus improving efficiency. SiC devices can also operate at higher temperatures and have desirable switching characteristics (e.g., higher switching frequencies) when compared to Si devices. However, manufacturing processes for Si devices cannot be used for manufacturing SiC devices. For example, the hardness of SiC is greater than the hardness of Si, hence processes typically used for Si devices may not be applicable to SiC devices.

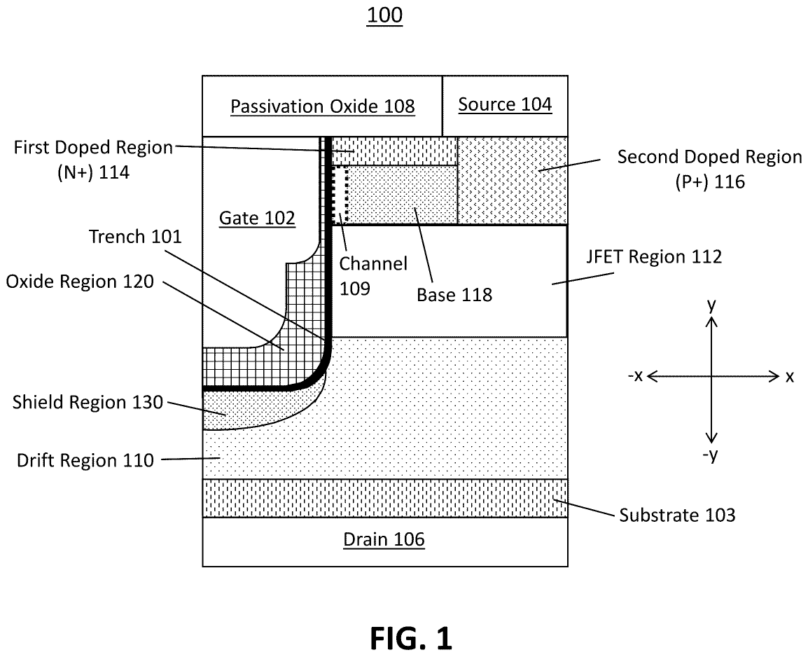

FIG. 1 illustrates a side view of an example of a portion of a two-step oxide trench Silicon Carbide MOSFET in one embodiment. A side view of a portion of a semiconductor device 100, or device 100 herein, is shown in FIG. 1. Device 100 can be formed using a substrate 103 that includes a gate region 102 (or gate electrode, herein “gate 102”), a source terminal 104 (herein “source 104”), a drain terminal 106 (herein “drain 106”), a layer of passivation oxide 108, a drift region 110, a junction field effect transistor (JFET) region 112, a first doped region 114, a second doped region 116, a base 118, an oxide region 120 and a shield region 130. Substrate 103 can be a semiconductor substrate that is doped with impurities of a first type, such as N-type impurities, such that substrate 103 is of a first conductivity type. In the descriptions herein, the first conductivity type can be either N-type or P-type and a second conductivity type can have opposite conductivity from the first conductivity type. For example, when the first conductivity type is N-type, second conductivity type is P-type, and vice versa.

Device 100 can be a SiC trench MOSFET. In one embodiment, device 100 can be one SiC trench MOSFET among a plurality of SiC trench MOSFETs in an integrated circuit. The trench MOSFET can be formed by etching a trench 101 vertically (e.g., in the −y direction) into a SiC substrate (e.g., substrate 103) and doping the remaining SiC substrate with impurities of different types and/or concentrations. Walls of trench 101 can be lined with a layer of gate oxide (e.g., oxide region 120, which will be further described below), and the lined trench 101 can be filled with a conductive material, such as polysilicon, forming the gate 102. Source 104 can be a region of the first conductivity type and drain 106 can be a region of the first conductivity type. Passivation oxide 108 can be a layer of oxide that is deliberately formed to function as a barrier to protect device 100 from environmental factors such as moisture, chemicals, and environmental pollutants that could compromise functionality of device 100.

Drift region 110 can be located between base 118 and substrate 103, and can extend along the walls of the trench 101 where gate 102 is located. Drift region 110 can be a region where carriers (e.g., electrons or holes) can drift from the source 104 to the drain 106. When a voltage is applied to the gate 102, an electric field is generated to form an inversion layer in a channel region (hereinafter “channel”) 109. In an embodiment, the channel 109 can be of the second conductivity type and have a dopant concentration varying between approximately 1×10¹⁵ cm⁻³ and approximately 1×10¹⁸ cm⁻³. In some embodiments, impurities of the first type can be used to form channel 109, enabling N-channel depletion mode MOSFET operations. The electric field can direct the carriers to move towards the drain 106, thus allowing current to flow from source 104 to drain 106. The strength and distribution of the electric field in drift region 110 can impact various electrical characteristics, such as on-resistance (RDSon), breakdown voltage, or other characteristics of device 100.

Device 100 can further include JFET region 112 formed within drift region 110 that provides a direct junction between the gate 102 and the channel 109. In an embodiment, the JFET region 112 can be located between a top surface of drift region 110, adjacent to trench 101, and bottom surfaces of channel 109, base 118 and second doped region 116. In some instances, JFET region 112 can be formed with a higher donor doping of the first conductivity type that can vary between, for example, 1×10¹⁶ cm⁻³ and 1×10¹⁸ cm⁻³.

First doped region 114 can be a region that is doped with impurities of a first type, such as N-type impurities. Second doped region 116 can be a region that is doped with impurities of a second type, such as P-type impurities. First doped region 114 can have the first conductivity type and second doped region 116 can have the second conductivity type. First doped region 114 and second doped region 116 can be in contact with source 104. First doped region 114 can be in contact with passivation oxide 108. When device 100 is an N-type device, first doped region 114 can be referred to as a first doped region and second doped region 116 can be referred to as a second doped region. In some aspects, first doped region 114 can also be referred to as the heavily doped region. If the first conductivity type is N-type, then first doped region 114 can be created by, for example, ion implantation or diffusion where N-type dopants such as Phosphorus (P) or Arsenic (As) are implanted into the region that eventually become first doped region 114. If the first conductivity type is N-type, then second doped region 116 can be created by, for example, ion implantation or diffusion where P-type dopants such as Boron (B), Aluminum (Al) or Gallium (Ga) are implanted into the region that eventually become second doped region 114. The depth and doping concentration of first doped region 114 and the second doped region 116 can be controlled to define the RDSon and breakdown voltage of device 100. For example, a doping concentration of the first dope region 114 can be of approximately 1×10¹⁹ cm⁻³ to approximately 1×10²¹ cm⁻³, while a doping concentration of second doped region 116 can be of approximately 1×10¹⁸ cm⁻³ to approximately 1×10²¹ cm⁻³.

Base 118 can be doped with impurities of the second type (e.g., same as second doped region 116), such as P-type impurities. The impurity concentration of impurities being used for doping base 118 can be less than the impurity concentration of second doped region 116. By having smaller impurity concentration than second doped region 116, base 118 can facilitate majority carriers injected from the emitter (e.g., source 104) to traverse the base 118 and reach the collector (e.g., drain 106). In an embodiment, a doping concentration of the base 118 can vary between approximately 1×10¹⁶ cm⁻³ to approximately 1×10¹⁸ cm⁻³. In some embodiments, base 118 can be lightly doped with impurities of the first type to achieve an accumulation-mode MOSFET (ACCUFET), in such cases the doping concentration of base 118 can vary between approximately 1×10¹⁴ cm⁻³ to approximately 1×10¹⁶ cm⁻³. In other embodiments, base 118 can be doped with impurities of the first type to achieve a depletion-mode MOSFET, in such cases the doping concentration of base 118 can vary between approximately 1×10¹⁶ cm⁻³ to approximately 1×10¹⁸ cm⁻³.

In an aspect, the layer of oxide layer lining the trench 101, or gate oxide, can be an insulating material that separates the gate 102 from the semiconductor channel (e.g., channel 109) and other conductive layers or regions of device 100. The insulating material lining trench 101 can be, for example, Silicon Dioxide (SiO2) or other high-k dielectrics. The layer of oxide can also help to control the flow of current between source 104 and drain 106 by modulating the electric field in drift region 110. A thinner layer of gate oxide can provide relatively more efficient control over the channel and a thicker layer of gate oxide can prevent gate oxide breakdown. The threshold voltage of device 100 can also be controlled by the thickness of the gate oxide. If the electric field in drift region 110 is too high, the gate oxide can degrade over time and negatively impact the overall lifespan and reliability of device 100. The oxide degradation can lead to shifts in the threshold voltage. For trench MOSFETs, the trench tends to have a relatively deeper profile (e.g., along the y-axis) compared to its width (e.g., x-axis). Thus, the electric field lines tend to concentrate at the bottom of the trench causing the electric field underneath the trench (e.g., −y direction) to be higher than other regions, such as near the sidewalls of the trench.

In some conventional devices, to mitigate the high electric field at the bottom of the trench, a P-shield, which is a P-type implant, can be positioned underneath the trench to mitigate the high electric field generated at the trench's bottom. However, the addition of the P-shield can compromise the ideal spread resistance. The spread resistance is the resistance encountered by current as the current spreads out from the gate to other regions of the device. As the area of contact between gate and other regions of the device increases, the spread resistance can be reduced, leading to lower RDSon and improving performance of the device. The addition of the P-shield can reduce the area of contact between gate and other regions of the device, thus increasing the spread resistance.

In some conventional devices, the bottom portion of the gate oxide lining the trench can be made to be thicker to reduce the electric field at the bottom of the trench. However, thermally growth thick oxide in SiC can be challenging. For example, Silicon (Si) and Carbon (C) has strong covalent bonds that are difficult to break, making it challenging for oxygen to react with SiC and to form a stable oxide layer, and more energy is required to break the bonds to allow oxidation to occur. Further, SiC has thermal stability that can withstand high temperatures without degrading, thus it is less reactive to oxygen at high temperatures and requiring more aggressive conditions to form the oxide layer, and also making it difficult to achieve thicker and smoother oxide layer.

Also, conventional techniques to reduce electric field at the bottom of the trench does not alleviate the high electric field at the corner of the trench and the lower part of the trench's side walls. Some conventional techniques include extending the P-shield underneath the trench laterally (e.g., along the x-axis) to reduce electric field at the corner of the trench, but when the P-shield is wider extending past the gate oxide, the spread resistance increases. To be described in more detail below, device 100 can have a gate oxide labeled as oxide region 120 that has a bottom portion and a lower side portion that are thicker than an upper side portion, along with a P-shield labeled as shield region 130 that does not extend past the gate oxide in the lateral direction (e.g., does not extend past the trench sidewall). The oxide region 120 can be manufactured using a multi-step (e.g., two-step) process that independently controls the thicknesses of the bottom potion, the lower side portion and the upper side portion of oxide region 120. Further, due to the different thickness, specifically the thicker lower side portion of oxide region 120, the shield region 130 can be manufactured to have a width that does not extend past the gate oxide.

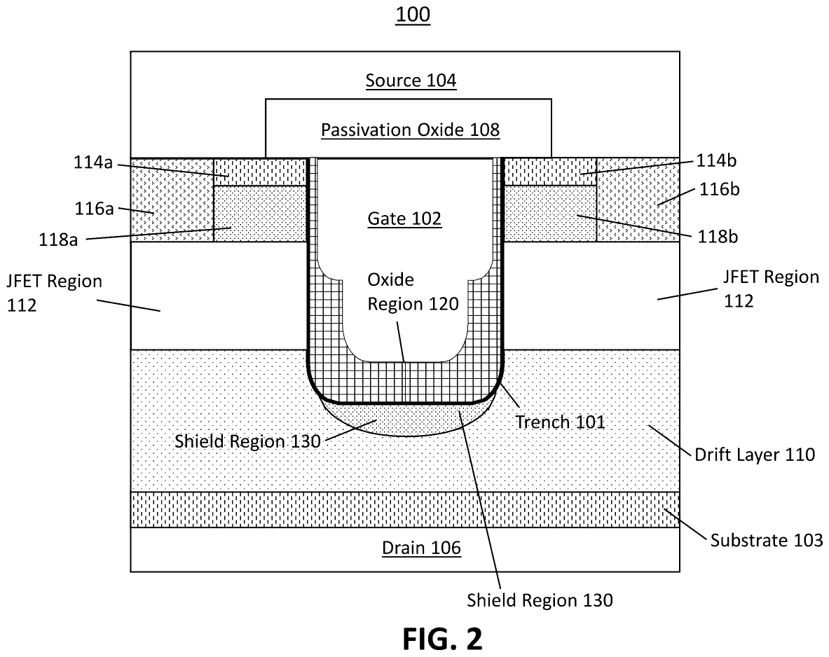

FIG. 2 illustrates an example of a two-step oxide trench Silicon Carbide MOSFET in one embodiment. Descriptions of FIG. 2 can reference components shown in FIG. 1. FIG. 2 shows a cross-sectional view of one whole unit, or one cell, of device 100 that implements a SiC trench MOSFET. As shown in FIG. 2, trench 101 is etched and formed between two first doped region regions 114a, 114b (e.g., first doped region), two second doped region regions 116a, 116b (e.g., second doped region) and two base regions 118a, 118b. Trench 101, in its entirety as shown in FIG. 2, can have a U shape and shield region 130 can span across the bottom portion of the trench 101 without extending past the sidewalls of trench 101. The oxide region 120 has a thick bottom portion, thick lower side portions on lower portions of the side of oxide region 120, and thin upper side portions on upper portions of the side of oxide region 120.

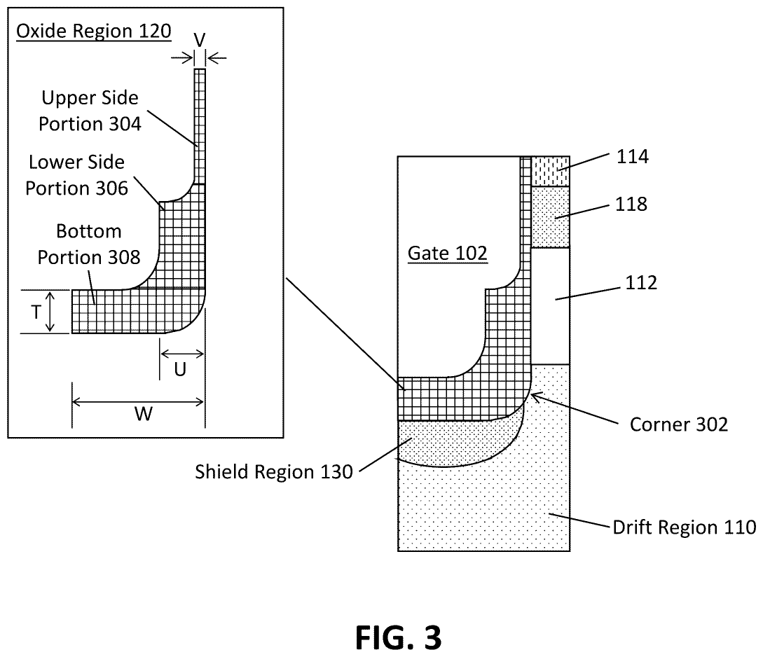

FIG. 3 illustrates an example of an oxide region 120 in a two-step oxide trench Silicon Carbide MOSFET in one embodiment. Description of FIG. 3 can reference components shown in FIG. 1 and FIG. 2. As shown in FIG. 3, oxide region 120 can include an upper side portion 304, a lower side portion 306 and a bottom portion 308. A thickness of upper side portion 304 is labeled as V. For example, thickness V can vary between approximately 1 nm to approximately 20 nm. A thickness of lower side portion 306 is labeled as U. For example, thickness U can vary between approximately 1 nm to approximately 500 nm. A thickness of bottom portion 308 is labeled as T. For example, thickness T can vary between approximately 1 nm to approximately 500 nm. The thickness U and the thickness T can be greater than the thickness V. The thickness U and T can be the same or can be different.

Bottom portion 308 can be in contact with shield region 130. Bottom portion 308 and shield region 130 can contribute to reduction of electric field in drift region 110 near the bottom of trench 101, such as underneath trench 101. Upper side portion 304 can be in contact with at least one of the first doped region 114, base 118 and JFET region 112. Lower side portion 306 can be in contact with JFET region 112 and drift region 110. Lower side portion 305 can contribute to reduction of electric field in drift region 110 near portions of the sidewalls of trench 101 and a corner 302 of trench 101. The utilization of lower side portion 306 to reduce electric field in drift region 110 near corner 302 can allow bottom portion 308 to have a width W that is less than or equal to a width of trench 101. In other words, bottom portion 308 does not need to be extended past a sidewall of trench 101 to reduce electric field near corner 302. Note that the width W of bottom portion 308 can be sized to not extend past the sidewalls of trench 101 and to be non-overlapping with corner 302.

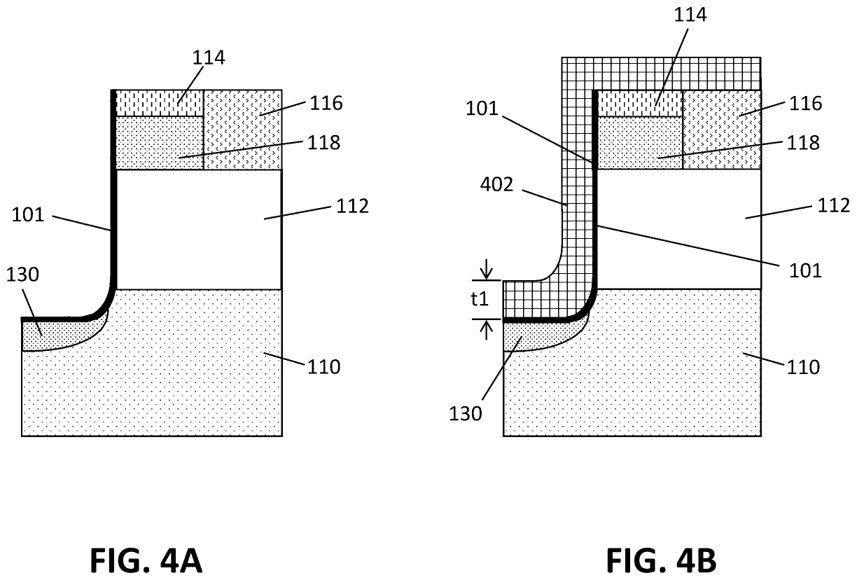

FIG. 4A to FIG. 8B illustrate a series of steps in a manufacturing process of a two-step oxide trench Silicon Carbide MOSFET in one embodiment. Descriptions of FIG. 4A to FIG. 8C can reference components shown in FIG. 1 to FIG. 3. In FIG. 4A, shield region 130 can be implanted into a stack comprising first doped region 114, second doped region 116, base 118 and drift region 110. Implantation of shield region 130 can include various techniques such as using a photomask or an implant mask to selectively block or allow the implantation of dopants of the second conductivity type (e.g., Aluminum) in the location of shield region 130 in drift region 110. By way of example, an ion implanter can be used for introducing ions of dopant material into the SiC lattice to create shield region 130 of the second conductivity type. Annealing can be performed to activate the dopants, repair damage to the substrate caused by the ion implantation, and to ensure that the dopants are properly incorporated into the lattice. In an embodiment, the shield region 130 can have a dopant concentration varying between approximately 1×10¹⁵ cm⁻³ and 5×10¹⁷ cm⁻³. A (vertical) depth of trench 101 into the drift region 110 (e.g., in the −y direction) can be of approximately 0.5 mm to approximately 10 mm, and preferably between approximately 0.5 mm to approximately 2 mm.

In FIG. 4B, after implanting shield region 130, a layer of oxide (hereinafter “oxide”) 402 having a thickness of t1 can be formed to line the walls of trench 101. The oxide 402 can be formed by thermal oxidation of an oxide material. However, in some embodiments, the oxide 402 can be formed by conformal deposition of the oxide material. The oxide 402 can be, for example, high-quality oxide that has relatively superior properties compared to other oxides in terms of purity, stability, or specific functional characteristics. The oxide 402 can be formed by oxides such as, for example, Silicon Dioxide (SiO2). The duration of oxidation to form oxide 402 can be controlled to define the thickness t1, which in turn determines the thickness T of bottom portion 308. For example, the oxidation process can be controlled to achieve an oxide 402 having a thickness t1 varying between approximately 1 nm to approximately 500 nm.

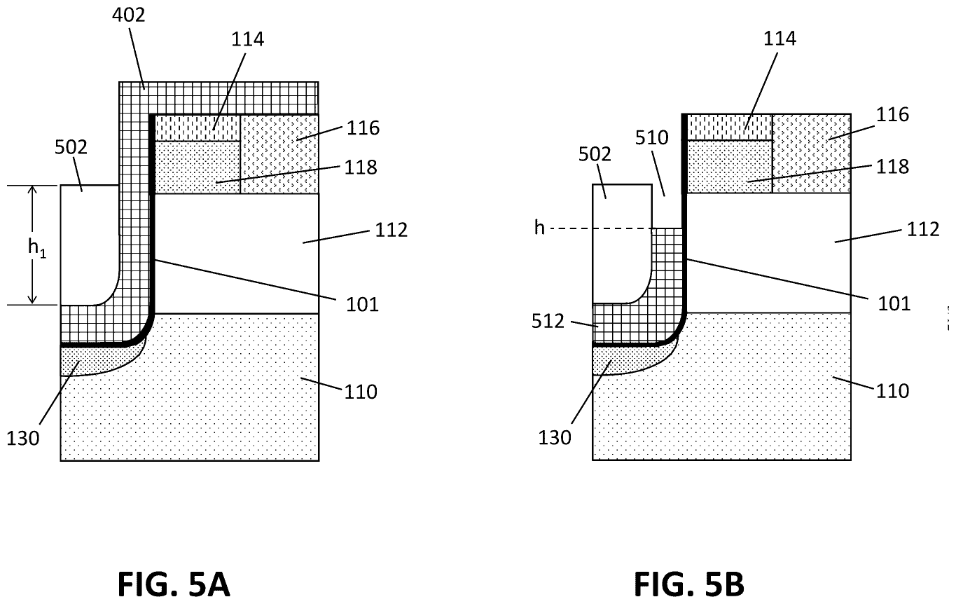

In FIG. 5A, after lining trench 101 with the oxide 402, a conductive material 502, such as polysilicon, can be deposited into the trench 101 lined with oxide 402. The conductive material 502 substantially fills a bottom portion of trench 101. In an embodiment, a thickness h1 of the conductive material 502 deposited within trench 101 can be of approximately 0 mm to approximately 1 mm. However, the thickness h1 of the conductive material 502 can vary based on the depth of the trench, ranging from 0% to 50% of the trench depth. The thickness h1 of the conductive material 502 can determine a location of a topmost portion of the lower side portion 306 of oxide region 120 described below.

In FIG. 5B, the layer of oxide 402 can be etched and a remaining portion of the layer of oxide is labeled as oxide 512. The conductive material 502 deposited in FIG. 5A can function as a mask during the etching of oxide 402, and the etching can result in a recess 510 formed between conductive material 502 and the sidewall of trench 101. In one embodiment, the etching rate can be controlled such that a height of oxide 512 along the sidewalls of trench 101 can reach a height of h. The height of h can define a contact point of upper side portion 304 and lower side portion 304. Etching of oxide 402 can include various wet and dry etching techniques that selectively remove oxide materials of oxide 402 but not conductive material 502.

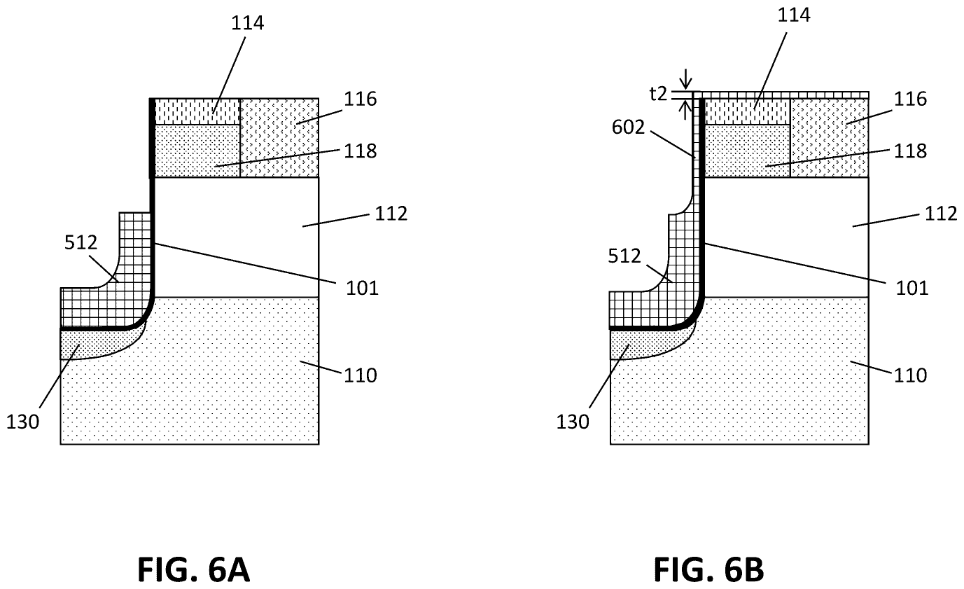

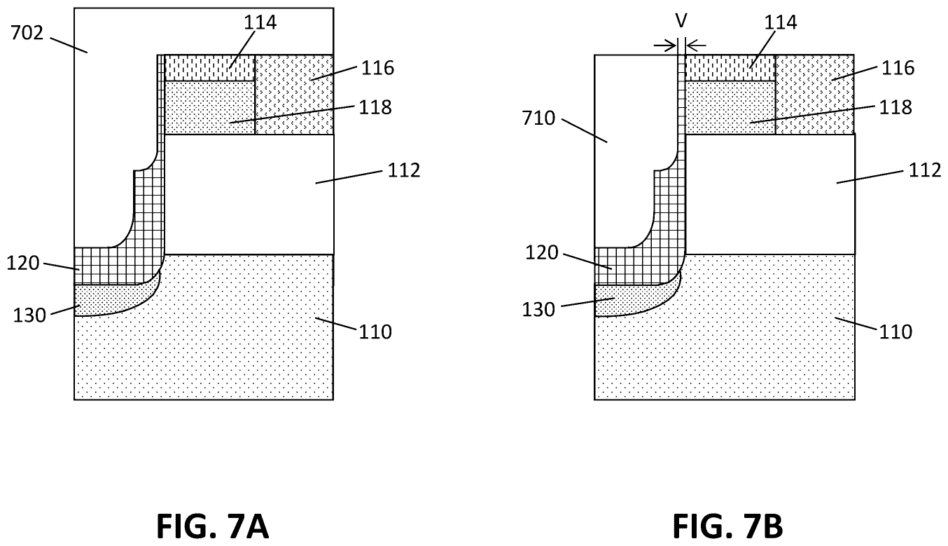

In FIG. 6A, the conductive material 502 can be removed using various wet and dry etching techniques that selectively remove the conductive material 502 but not oxide 512. In FIG. 6B, a layer of oxide 602 having a thickness of t2 can be formed on a top surface of oxide 512 and portions of the walls of trench 101 that are exposed (e.g., not covered or lined by oxide 512). The layer of oxide 602 can also be formed on a top surface of first doped region 114 and second doped region 116. The layer of oxide 602 can be formed by oxidation, with the thickness t2 varying between approximately 1 nm to approximately 20 nm. The layer of oxide can be, for example, a high-quality oxide that has relatively superior properties compared to other oxides in terms of purity, stability, or specific functional characteristics. The layer of oxide 602 can be formed by oxides such as, for example, SiO₂. The combination of oxide 512 and oxide 602 can form the oxide region 120. The duration of oxidation to form oxide 602 can be controlled to define the thickness t2, which in turn determines the thickness V of upper side portion 304 (shown in FIG. 6B). Since the duration of oxidation to define thickness t1 of oxide 402 and to define thickness t2 of oxide 602 can be controlled independently, or in separate steps, the thickness T of bottom portion 308 and thickness U of lower side portion 306 can be achieved separately from the thickness V of the upper side portion 304. This allows controlling an amount of electric field reduction at the bottom, side and corner of trench 101. As mentioned above, oxidation on SiC substrate to form relatively thick oxide can be challenging. To address this challenge, the process described herein can form oxide 402 and oxide 602 in different steps, where oxides 402, 602 can be combined to form an oxide region 120 of varying thickness as depicted in FIG. 7A.

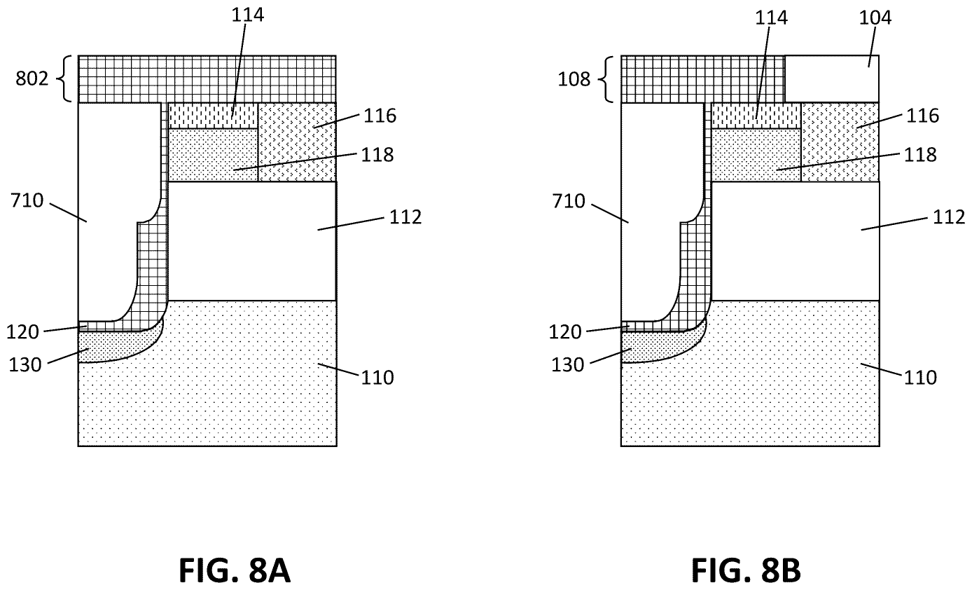

In FIG. 7A, conductive material 702, such as polysilicon, can be deposited on top of oxide region 120, first doped region 114 and second doped region 116. In FIG. 7B, the conductive material 702 can be etched such that parts of conductive material 702 on top of first doped region 114 and second doped region 116 can be removed, and a top of the remaining of conductive material 702, labeled as conducive material 710, can be aligned with the top of first doped region 114 and second doped region 116, as shown in FIG. 7B. In FIG. 8A, additional layer of oxide 802 can be formed on top of conductive material 710 by oxidation. Oxide 802 can be, for example, high-quality oxide that has relatively superior properties compared to other oxides in terms of purity, stability, or specific functional characteristics. The layer of oxide 802 can be formed by oxides such as, for example, SiO2. In FIG. 8B, the additional layer of oxide 802 can be etched to shape the passivation oxide 108 shown in FIG. 1. After the etching, source 104 can be added.

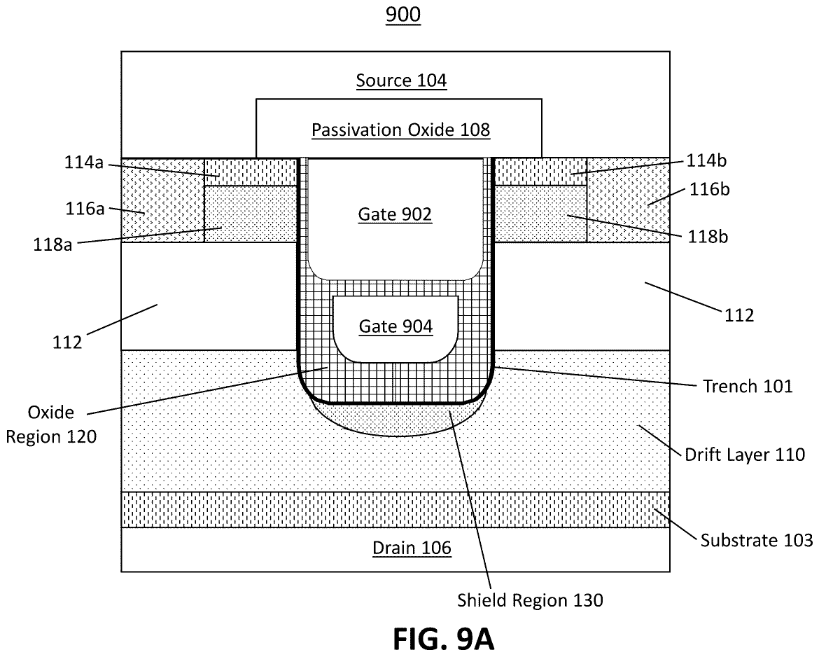

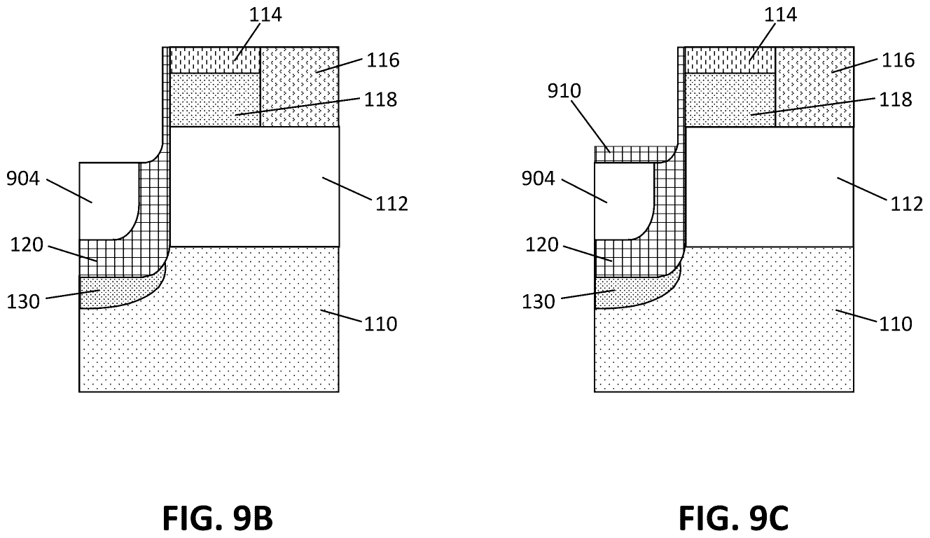

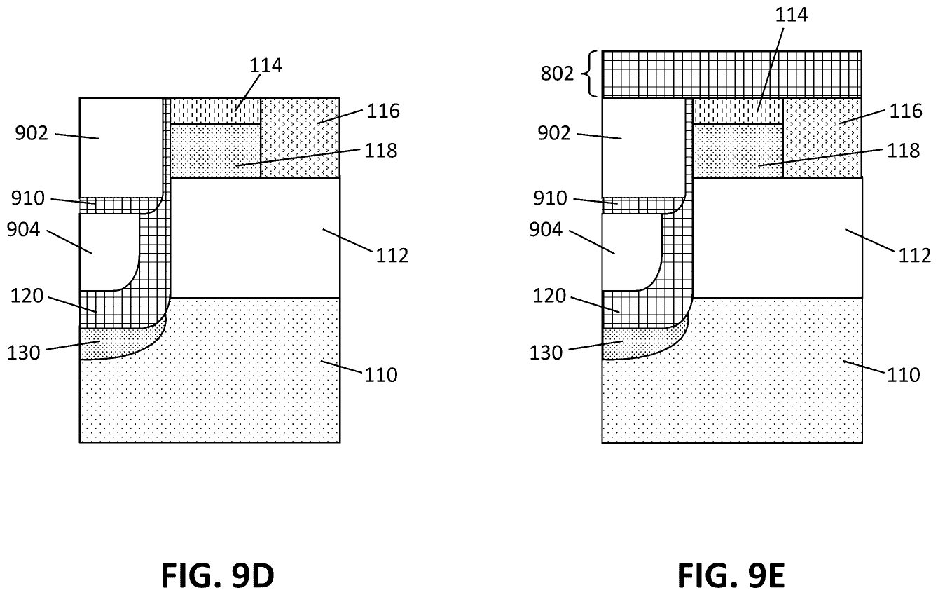

FIG. 9A illustrates another example of a two-step oxide trench Silicon Carbide MOSFET in one embodiment. Descriptions of FIG. 9A can reference components shown in FIG. 1 to FIG. 8B. In one embodiment, FIG. 9A shows one whole unit, or one cell, of a device 900 that implements a SiC trench MOSFET having a split gate arrangement along with the oxide region 120 and the shield region 130 described herein. Device 900 can be a split gate trench MOSFET including at least two gate electrodes 902, 904. Oxide region 120 can be disposed between gates 902, 904 and trench 101. In another embodiment, device 900 shown in FIG. 9A can implement a SiC trench MOSFET having a shield gate arrangement along with the oxide region 120 and the shield region 130 described herein, such that gate electrode 904 can serve as a shield and can have a different doping concentration from gate electrode 902. FIG. 9B to FIG. 9E illustrate a series of steps in a manufacturing process of device 900.

FIG. 9B shows a step that follows FIG. 7A. In FIG. 9B, the conductive material 702 can be etched such that parts of conductive material 702 on top of first doped region 114 and second doped region 116, and some parts that are in trench 101, can be removed. The remainder of conductive material 702 forms the gate 904. In FIG. 9C, a layer of oxide 910 can be formed to on top of gate 904 by oxidation. Oxide 910 can be, for example, SiO2. In FIG. 9D, conductive material forming gate 902 can be deposited on oxide 910. In FIG. 9E, the additional layer of oxide 802 can be added on top of the entire stack shown in FIG. 9D to form the passivation oxide 108 shown in FIG. 9A.

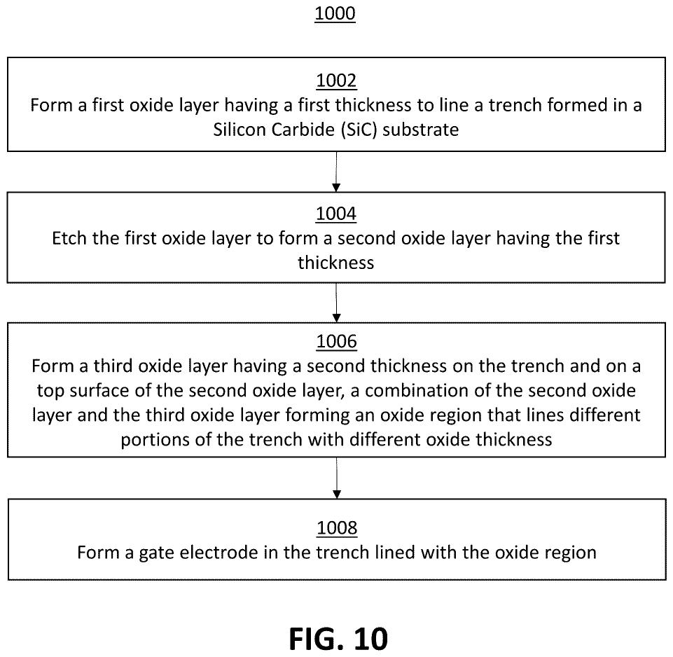

FIG. 10 is a flow diagram illustrating a process to manufacture a two-step oxide trench Silicon Carbide MOSFET in one embodiment. Process 1000 in FIG. 10 can be performed to manufacture semiconductor devices, such as device 100 and/or device 900 described herein. An example process may include one or more operations, actions, or functions as illustrated by one or more of blocks 1002, 1004, 1006, and/or 1008. Although illustrated as discrete blocks, various blocks may be divided into additional blocks, combined into fewer blocks, eliminated, performed in different order, or performed in parallel, depending on the desired implementation.

Process 1000 can begin at block 1002. At block 1002, a first oxide layer having a first thickness can be formed to line a trench formed in a Silicon Carbide (SiC) substrate. In one embodiment, a shield region can be formed underneath the trench prior to forming the first oxide layer. A width of the shield region can be less than or equal to a width of the trench. The shield region can be non-overlapping with a sidewall of the trench.

Process 1000 can proceed from block 1002 to block 1004. At block 1004, the first oxide layer can be etched to form a second oxide layer having the first thickness. A portion of the trench being lined by the second oxide layer can be less than a portion of the trench being lined by the first oxide layer. In one embodiment, etching the first oxide layer to form the second oxide layer can include depositing a conductive material on the first oxide layer, etching a portion of the first oxide layer that is non-overlapping with the conductive material, and removing the conductive material to form the second oxide layer.

Process 1000 can proceed from block 1004 to block 1006. At block 1006, a third oxide layer having a second thickness can be formed on the trench and on the second oxide layer. A combination of the second oxide layer and the third oxide layer can form an oxide region that lines different portions of the trench with different oxide thickness. In one embodiment, the oxide region can include a bottom portion, a lower side portion and an upper side portion. A thickness of the bottom portion is greater than a thickness of the upper side portion. A thickness of the lower side portion is greater than the thickness of the upper side portion. The thickness of the bottom portion and the thickness of the lower side portion can be equal to the first thickness. The thickness of the upper side portion is the second thickness.

Process 1000 can proceed from block 1006 to block 1008. At block 1008, a gate electrode can be formed in the trench lined with the oxide region. In one embodiment, a third oxide layer can be formed on the gate electrode. Another gate electrode can be formed on top of the third oxide layer. A passivation oxide layer can be formed on said another gate electrode.

### EXAMPLES

Example 1. A method of forming a semiconductor device, comprising:
forming a first oxide layer having a first thickness to line a trench formed in a Silicon Carbide (SiC) substrate;
etching the first oxide layer to form a second oxide layer having the first thickness, wherein a portion of the trench being lined by the second oxide layer is less than a portion of the trench being lined by the first oxide layer;
forming a third oxide layer having a second thickness on the trench and on a top surface of the second oxide layer, wherein a combination of the second oxide layer and the third oxide layer forms an oxide region that lines different portions of the trench with different oxide thickness; and
forming a gate electrode in the trench lined with the oxide region.

Example 2. The method according to Example 1, further comprising:
forming a shield region underneath the trench prior to forming the first oxide layer.

Example 3. The method according to Example 2, wherein a width of the shield region is less than or equal to a width of the trench.

Example 4. The method according to Example 2, wherein the shield region is non-overlapping with a sidewall of the trench.

Example 5. The method according to Example 1, wherein an impurity concentration of the shield region is in a range of 1×10¹⁵ cm⁻³ to 5×10¹⁷ cm⁻³.

Example 6. The method according to any one of Examples 1 to 5, wherein etching the first oxide layer to form the second oxide layer comprises:
depositing a conductive material on the first oxide layer;
etching a portion of the first oxide layer that is non-overlapping with the conductive material; and
removing the conductive material to form the second oxide layer.

Example 7. The method according to any one of Examples 1 to 6, wherein:
the oxide region comprises a bottom portion, a lower side portion and an upper side portion;
a thickness of the bottom portion is greater than a thickness of the upper side portion; and
a thickness of the lower side portion is greater than the thickness of the upper side portion.

Example 8. The method according to any one of Examples 1 to 7, wherein:
the thickness of the bottom portion and the thickness of the lower side portion is the first thickness; and
the thickness of the upper side portion is the second thickness.

Example 9. The method according to Example 7, wherein a thickness of the bottom portion of the oxide region is in a range of 1 nm to 500 nm.

Example 10. The method according to Example 7, wherein a thickness of the lower side portion of the oxide region is in a range of 1 nm to 500 nm.

Example 11. The method according to any one of Examples 1 to 8, further comprising:
forming a fourth oxide layer on the gate electrode;
forming another gate electrode on top of the fourth oxide layer; and
forming a passivation oxide layer on said another gate electrode.

Example 12. A method of forming a semiconductor device, comprising:
forming a first oxide layer having a first thickness to line a trench formed in a Silicon Carbide (SiC) substrate;
etching the first oxide layer to form a second oxide layer having the first thickness;
forming a third oxide layer having a second thickness on the trench and on a top surface of the second oxide layer, a combination of the second oxide layer and the third oxide layer creates an oxide region lining the trench, wherein the oxide region includes a bottom portion, a lower side portion and an upper side portion lining different parts of the trench; and
forming a gate electrode in the trench lined with the oxide region.

Example 13. The method according to Example 12, further comprising:
forming a shield region underneath the trench prior to forming the first oxide layer.

Example 14. The method according to Example 12, wherein a width of the shield region is less than or equal to a width of the trench.

Example 15. The method according to Example 12, wherein the shield region is non-overlapping with a sidewall of the trench.

Example 16. The method according to anyone of Examples 12 to 15, wherein etching the first oxide layer to form the second oxide layer comprises:
depositing a conductive material on the first oxide layer;
etching a portion of the first oxide layer that is non-overlapping with the conductive material; and
removing the conductive material to form the second oxide layer.

Example 17. The method according to any one of Examples 12 to 16, wherein:
a thickness of the bottom portion is greater than a thickness of the upper side portion; and
a thickness of the lower side portion is greater than the thickness of the upper side portion.

Example 18. The method according to any one of Examples 12 to 17, wherein:
the thickness of the bottom portion and the thickness of the lower side portion are equal to the first thickness; and
the thickness of the upper side portion is the second thickness.

Example 19. A method of forming a semiconductor device, comprising:
forming a trench within a Silicon Carbide (SiC) substrate;
forming a shield region on a bottom portion of the trench;
forming a first oxide layer having a first thickness to line the trench, the first oxide layer being disposed above the shield region;
depositing a conductive material on the first oxide layer;
etching a portion of the first oxide layer that is non-overlapping with the conductive material to form a second oxide layer having the first thickness;
conducting an oxidation process to form a third oxide layer, having a second thickness, on a top surface of the second oxide layer, a combination of the second oxide layer and the third oxide layer creates an oxide region of varying thickness, wherein the oxide region includes a bottom portion, a lower side portion and an upper side portion each lining different parts of the trench; and
forming a gate electrode in the trench lined with the oxide region.

Example 20. The method according to Example 19, wherein:
a thickness of the bottom portion is greater than a thickness of the upper side portion, the thickness of the bottom portion is the first thickness; and
a thickness of the lower side portion is greater than the thickness of the upper side portion, the thickness of the lower side portion is the first thickness and the thickness of the upper side portion is the second thickness.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of forming a semiconductor device, comprising:
forming a first oxide layer having a first thickness to line a trench formed in a Silicon Carbide (SiC) substrate;
etching the first oxide layer to form a second oxide layer having the first thickness, wherein a portion of the trench being lined by the second oxide layer is less than a portion of the trench being lined by the first oxide layer;
forming a third oxide layer having a second thickness on the trench and on a top surface of the second oxide layer, wherein a combination of the second oxide layer and the third oxide layer forms an oxide region that lines different portions of the trench with different oxide thickness; and
forming a gate electrode in the trench lined with the oxide region.

2. The method according to claim 1, further comprising forming a shield region underneath the trench prior to forming the first oxide layer.

3. The method according to claim 2, wherein a width of the shield region is less than or equal to a width of the trench.

4. The method according to claim 2, wherein the shield region is non-overlapping with a sidewall of the trench.

5. The method according to claim 2, wherein an impurity concentration of the shield region is in a range of 1×10¹⁵ cm⁻³ to 5×10¹⁷ cm⁻³.

6. The method according to claim 1, wherein etching the first oxide layer to form the second oxide layer comprises:
depositing a conductive material on the first oxide layer;
etching a portion of the first oxide layer that is non-overlapping with the conductive material; and
removing the conductive material to form the second oxide layer.

7. The method according to claim 1, wherein:
the oxide region comprises a bottom portion, a lower side portion and an upper side portion;
a thickness of the bottom portion is greater than a thickness of the upper side portion; and
a thickness of the lower side portion is greater than the thickness of the upper side portion.

8. The method according to claim 7, wherein:
the thickness of the bottom portion and the thickness of the lower side portion are equal to the first thickness; and
the thickness of the upper side portion is the second thickness.

9. The method according to claim 1, wherein a thickness of a bottom portion of the oxide region is in a range of 1 nm to 500 nm.

10. The method according to claim 1, wherein a thickness of the lower side portion of the oxide region is in a range of 1 nm to 500 nm.

11. The method according to claim 1, further comprising:
forming a fourth oxide layer on the gate electrode;
forming another gate electrode on top of the fourth oxide layer; and
forming a passivation oxide layer on said another gate electrode.

12. A method of forming a semiconductor device, comprising:
forming a first oxide layer having a first thickness to line a trench formed in a Silicon Carbide (SiC) substrate;
etching the first oxide layer to form a second oxide layer having the first thickness;
forming a third oxide layer having a second thickness on the trench and on a top surface of the second oxide layer, a combination of the second oxide layer and the third oxide layer creates an oxide region lining the trench, wherein the oxide region includes a bottom portion, a lower side portion and an upper side portion of varying thickness lining different parts of the trench; and
forming a gate electrode in the trench lined with the oxide region.

13. The method according to claim 12, further comprising forming a shield region underneath the trench prior to forming the first oxide layer.

14. The method according to claim 13, wherein a width of the shield region is less than or equal to a width of the trench.

15. The method according to claim 13, wherein the shield region is non-overlapping with a sidewall of the trench.

16. The method according to claim 12, wherein etching the first oxide layer to form the second oxide layer comprises:
depositing a conductive material on the first oxide layer;
etching a portion of the first oxide layer that is non-overlapping with the conductive material; and
removing the conductive material to form the second oxide layer.

17. The method according to claim 12, wherein:
a thickness of the bottom portion is greater than a thickness of the upper side portion; and
a thickness of the lower side portion is greater than the thickness of the upper side portion.

18. The method according to claim 17, wherein:
the thickness of the bottom portion and the thickness of the lower side portion are equal to the first thickness; and
the thickness of the upper side portion is the second thickness.

19. A method of forming a semiconductor device, comprising:
forming a trench within a Silicon Carbide (SiC) substrate;
forming a shield region on a bottom portion of the trench;
forming a first oxide layer having a first thickness to line the trench, the first oxide layer being disposed above the shield region;
depositing a conductive material on the first oxide layer;
etching a portion of the first oxide layer that is non-overlapping with the conductive material to form a second oxide layer having the first thickness;
conducting an oxidation process to form a third oxide layer, having a second thickness, on a top surface of the second oxide layer, a combination of the second oxide layer and the third oxide layer creates an oxide region of varying thickness, wherein the oxide region includes a bottom portion, a lower side portion and an upper side portion each lining different parts of the trench; and
forming a gate electrode in the trench lined with the oxide region.

20. The method according to claim 19, wherein:
a thickness of the bottom portion is greater than a thickness of the upper side portion, the thickness of the bottom portion is first thickness; and
a thickness of the lower side portion is greater than the thickness of the upper side portion, the thickness of the lower side portion is the first thickness and the thickness of the upper side portion is the second thickness.
